(19) United States
(12) Patent Application Publication
(10) Pub. No.: US 2025/0172384 A1
(43) Pub. Date: May 29, 2025

(54) METHOD, MEASUREMENT SYSTEM, AND COMPUTER-READABLE MEDIUM FOR MEASURING HOLE DEPTH USING PHASE EXTRACTION INFORMATION FROM REFLECTANCE SPECTRUM

(71) Applicant: CHROMA ATE INC., Taoyuan City (TW)

(72) Inventor: SHIH-YAO PAN, Taoyuan City (TW)

(21) Appl. No.: 18/937,078

(22) Filed: Nov. 5, 2024

(30) Foreign Application Priority Data
Nov. 29, 2023 (TW) 112146405

(51) Int. Cl. G01B 11/22

(52) U.S. Cl. CPC G01B 11/22

(57) ABSTRACT

A method, measurement system and computer-readable medium for measuring a hole depth using phase extraction information from a reflectance spectrum. The method includes a step of acquiring a reflectance spectrum, a step of obtaining the correlation between the intensity and a wave number of a reflected light, a step of phase extraction and a step of determining a hole depth. By converting first distribution data between the intensity and the wave number of the reflected light into second distribution data between a phase and the wave number, information of the hole depth of a hole structure is obtained by calculating a slope value. Thus, a measurement resolution can be increased and the accuracy can be enhanced.

### BACKGROUND OF THE INVENTION

### Field of the Invention

The present invention relates to a measurement technique of a structure, and more particularly to a method, a measurement system and a computer-readable medium for measuring a hole depth using phase extraction information from a reflectance spectrum.

### Description of the Prior Art

In the technical field of semiconductor integrated circuits, in order to increase a space utilization rate and improve the bottleneck of data transmission, semiconductor integrated circuits have entered packaging processes of three-dimensional stacking (such as 2.5D or 3D), using bare die stacking to solve the aforementioned issues.

In these stacked structures, with a through silicon via (TSV) technique, signals of different chips can be connected together to increase the space utilization rate and reduce transmission distances, achieving improved transmission speeds of signals and electrical power.

In a TSV process, multiple steps are included respectively along with slight differences of manufacturing techniques. In general, these steps are, for example, via formation, via filling, chemical mechanical polishing (CMP), wafer thinning, wafer bonding and various TSV integration techniques (for example, via first/via last).

In the steps above, holes are the foundation of the entire TSV structure, and therefore depth sizes of holes play a critical role in the overall TSV processes and need to be accurately controlled. However, due to the structural feature of a high aspect ratio of vias of a TSV structure, measurement of depth sizes of holes may become extremely difficult and the accuracy also faces numerous challenges.

### SUMMARY OF THE INVENTION

In some embodiments disclosed by the present invention, a measurement resolution of a depth size of holes is increased to thereby enhance the accuracy.

A method for measuring a hole depth using phase extraction information from a reflectance spectrum is provided according to some embodiments of the present invention. The method includes: acquiring a reflectance spectrum from a target region, the target region having therein a hole structure with a high aspect ratio; obtaining first distribution data between the intensity and a wave number of a reflected light based on the reflectance spectrum; converting the first distribution data by a phase extraction process into second distribution data between a phase and the wave number; and determining a hole depth of the hole structure according to a slope value of at least one straight line presented by the second distribution data, and using a wavelength unit of the reflectance spectrum as a measurement unit of the hole depth.

According to some embodiments, when the second distribution data presents one single straight line, one half of the slope value of the straight line is the hole depth of the hole structure.

According to some embodiments, the phase extraction process may include: removing a DC term from the first distribution data; performing a Hilbert transform to obtain an analytical signal having a real part term in a cosine form and an imaginary part term in a sine form; and obtaining a distribution relationship between a phase and a wave number based on an arctangent function of the real part term and the imaginary part term, as the second distribution data.

According to some embodiments, the phase extraction process may include: converting the first distribution data into intermediate data having a real part term and an imaginary part term; performing a Fourier transform; performing a step of removing and filling points to preserve only one of the real part term and the imaginary part term, remove other data and fill a plurality of data points having a power density in a fixed value so as to maintain a data length; performing an inverse Fourier transform; and obtaining a distribution relationship between the phase and the wave number, as the second distribution data.

According to some embodiments, when a surrounding surface of the hole structure has a light permeable oxide layer, phase data in the first distribution data defines a hole depth phase and a film phase, and the second distribution data may present two straight lines. A slope value of the straight line having a greater slope between the two straight lines is a first value, and a slope value of the straight line having a smaller slope between the two straight lines is a second value. One half of the second value may be a thickness of the oxide layer. One half of a sum of the first value and the second value may be the hole depth of the hole structure. The wavelength unit of the reflectance spectrum may be a measurement unit of the thickness of the oxide layer.

A non-volatile computer-readable storage medium is further provided according to some embodiments of the present invention. The non-volatile computer-readable storage medium can store a computer program. The computer program is operable to be loaded into a computing processing device, and to prompt the computing processing device to perform the method above.

A measurement system for measuring a hole depth using phase extraction information from a reflectance spectrum is further provided according to some embodiments of the present invention. The measurement system includes a light interference measurement device and a computing processing device. The light interference measurement device is operable to acquire a reflectance spectrum from a target region. The computing processing device is coupled to the light interference measurement device, and is operable to perform the method above.

Accordingly, based on the relationship between the intensity and the wave number of the reflected light, the distribution relationship between the phase and the wave number is obtained by means of conversion. With the distribution relationship presenting a form of a straight line, the slope value is calculated to obtain hole depth information of a hole structure, and thickness information of the oxide layer can also be further obtained. Thus, a measurement resolution is increased and the accuracy is also enhanced.

### BRIEF DESCRIPTION OF THE DRAWINGS

FIG. 1 is a schematic diagram of a hole structure.

FIG. 2 is a schematic diagram of a measurement system according to some embodiments.

FIG. 3 is a flowchart of a method for measuring a hole depth using phase extraction information from a reflectance spectrum according to some embodiments.

FIG. 4 is a relationship diagram of the intensity and a wave number of a reflected light according to some embodiments.

FIG. 5 is a relationship diagram of the phase and the wave number of the embodiment in FIG. 4.

FIG. 6 is a relationship diagram of the intensity and a wave number of a reflected light with a DC term removed according to some embodiments.

FIG. 7 is a spectrogram of first distribution data having undergone a Fourier transform according to some embodiments.

FIG. 8 is a spectrogram of the embodiment in FIG. 7 having been processed.

FIG. 9 is a schematic diagram of a hole structure having an oxide layer.

FIG. 10 is a relationship diagram of the intensity and a wave number of a reflected light of a hole structure having an oxide layer.

FIG. 11 is a relationship diagram of the phase and the wave number of the embodiment in FIG. 10.

### DETAILED DESCRIPTION OF THE EMBODIMENTS

Objectives, features, and advantages of the present disclosure are hereunder illustrated with specific embodiments, depicted with drawings, and described below.

In the disclosure, descriptive terms such as “a” or “one” are used to describe the unit, component, structure, device, module, portion, section or region, and are for illustration purposes and providing generic meaning to the scope of the present invention. Therefore, unless otherwise explicitly specified, such description should be understood as including one or at least one, and a singular number also includes a plural number.

In the disclosure, descriptive terms such as “include, comprise, have” or other similar terms are not for merely limiting the essential elements listed in the disclosure, but can include other elements that are not explicitly listed and are however usually inherent in the units, components, structures, devices, modules, portions, sections or regions.

In the disclosure, the terms similar to ordinals such as “first” or “second” described are for distinguishing or referring to associated identical or similar components or structures, and do not necessarily imply the orders of these components, structures, portions, sections or regions in a spatial aspect. It should be understood that, in some situations or configurations, the ordinal terms could be interchangeably used without affecting the implementation of the present invention.

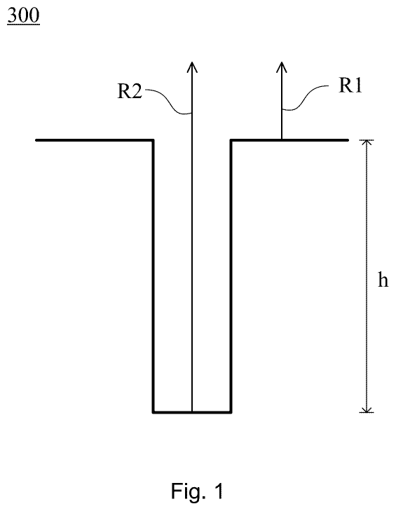

Refer to FIG. 1 showing a schematic diagram of a hole structure. After a detection light is provided to the hole structure having a hole depth h, an incident light forms a first reflected light R1 on a surrounding surface of a hole structure 300 and forms a second reflected light R2 at a hole bottom of the hole structure 300. Due to an optical path difference between the first reflected light R1 and the second reflected light R2, the hole depth h of the hole structure 300 can be obtained based on information of the optical path difference.

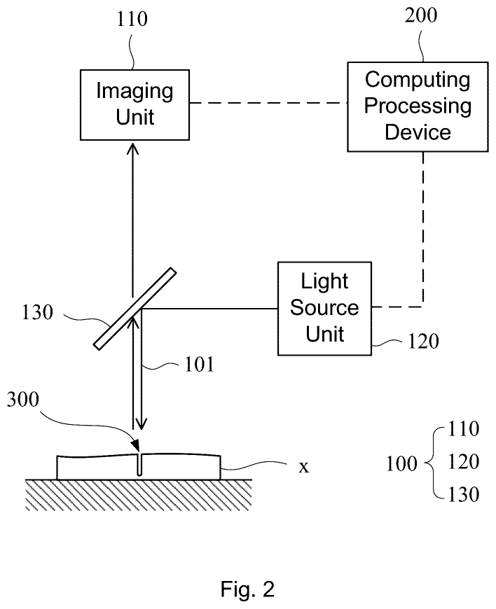

Refer to FIG. 2 showing a schematic diagram of a measurement system according to some embodiments. The measurement system includes a light interference measurement device 100 and a computing processing device 200. The light interference measurement device 100 is configured to provide an illumination light 101 to an object under test x having the hole structure 300 to scan a target region (with the illumination light provided to holes one after another or to regions one after another). A corresponding interference signal is obtained each time the illumination light is provided to each hole or each region. In some embodiments, a scanning and measurement operation of the light interference measurement device 100 is performed only on one single hole (providing the illumination light and acquiring a reflectance spectrum) at a time. Thus, related information of the hole structure can be more quickly and accurately determined.

By using a light source unit 120 and a spectroscopic unit 130 in a coaxial illumination configuration, the reflected light from the hole structure 300 can be captured by an imaging unit 110 to form a spectral signal. Due to the light path difference above, the imaging unit 110 can capture a spectral signal with occurrence of interference on the object under test having the hole structure 300. The computing processing device 200 is coupled to the light source unit 120 and the imaging unit 110 of the light interference measurement device 100, thereby controlling the scanning operation, receiving the spectral signal and performing subsequent processing steps such as phase extraction.

The configuring of the light interference measurement device 100 in FIG. 2 is merely an example, and the light interference measurement device 100 is, for example, a spectral interferometer or other types of interferometer. In sum, for a reflected light from a reference plane (for example, a surface) of an object under test and a reflected light from a hole bottom of a hole structure, any measurement device capable of acquiring these two reflected lights and obtaining the occurrence of light interference between the two is suitable for embodiments of the present invention. The computing processing device 200 may be one single computer, multiple computers, or one single computing processing module or multiple computing processing modules configured in an overall measurement system. The computing processing device 200 is operable to receive and process the spectral signal of the reflected light provided by the light interference measurement device 100.

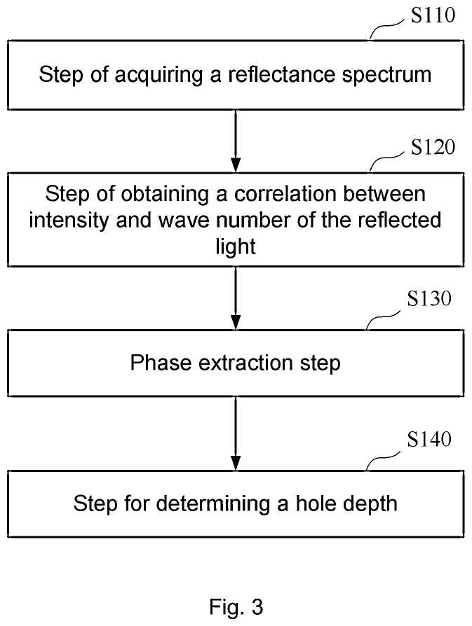

Refer to FIG. 3 showing a flowchart of a method for measuring a hole depth using phase extraction information from a reflectance spectrum according to some embodiments.

The computing processing device 200 is configured to perform the method for measuring a hole depth below.

Step S110 is a step of acquiring a reflectance spectrum. This step acquires a reflectance spectrum from a target region. The target region has therein a hole structure with a high aspect ratio. The target region may have only one single hole structure, or may have a plurality of hole structures.

Step S120 is a step of obtaining a correlation between the intensity and a wave number of the reflected light. This step converts the reflectance spectrum into a distribution relationship capable of presenting the correlation between the intensity and the wave number of the reflected light, so as to obtain first distribution data representing the correlation between the intensity and the wave number of the reflected light.

Step S130 is a phase extraction step. This step converts the first distribution data by a phase extraction process into a distribution relationship capable of presenting the correlation between a phase and the wave number, so as to obtain second distribution data representing the correlation between the phase and the wave number.

Step S140 is a step for determining a hole depth. This step determines a hole depth of the hole structure according to a slope value of at least one straight line presented by the second distribution data. The wavelength unit of the reflectance spectrum is used as a measurement unit of the hole depth.

Light exhibits sinusoidal wave characteristics, and distinct reflected lights from a surface around the hole structure (for example, the top of the hole) and a hole bottom of the hole structure can cause, based on an optical path difference, redistribution of light intensity in space, forming occurrence of interference. By extracting phase information from the reflectance spectrum, the distribution relationship between the phase and the wave number can be obtained, and this distribution relationship can be used to obtain hole depth information of the hole structure, while also further effectively increasing the resolution.

In some embodiments, in step S120, a corresponding light intensity value can be obtained based on wave numbers of the same interval. Accordingly, when the wavelength in data of the reflectance spectrum is converted into the wave number, an interpolation of the corresponding light intensity value can be obtained by using common interpolation methods or other methods.

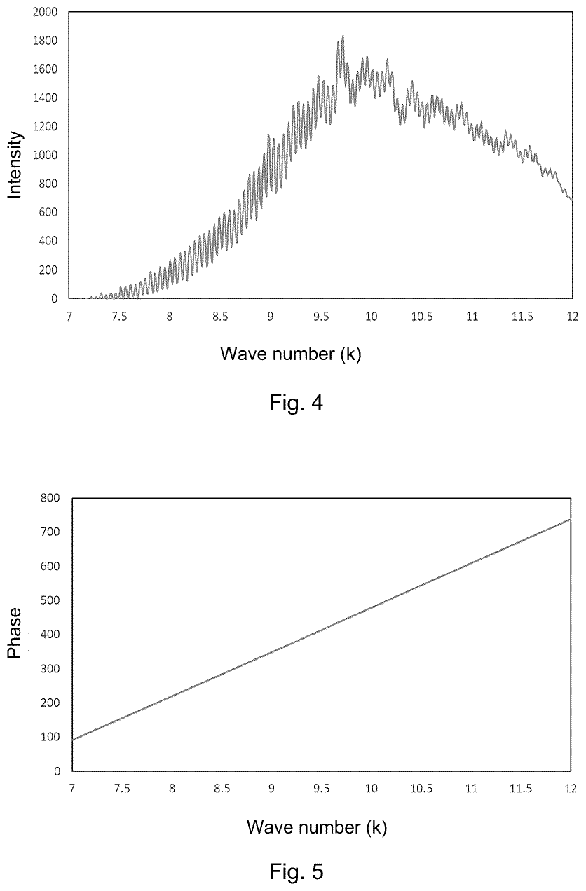

Next, refer to FIG. 4 showing a relationship diagram of the intensity and a wave number of a reflected light according to some embodiments. The wave number is the number of wavelengths within a length of 2π, and it may be said as the number of times of repeating fluctuations within a length of 2π. The wave number is defined as k, and so k=2π/λ.

When the reflectance spectrum has the occurrence of interference due to the light path difference, the light path difference is twice the hole depth (a distance of h is further traveled during incidence and reflection). The number of wavelengths λ within a distance of the light path difference (the hole depth h) can be represented as (2h/λ), which is multiplied by 2π to become the phase. As shown in equation (1), α(λ) and b(λ) represents the occurrence of different indices of reflection presented for different spectral wavelengths based on different substances, and α(λ) can represent the intensity of a background light.

$$I ( λ ) = a ( λ ) + b ( λ ) cos ( \frac{4 π h}{λ} + {φ}_{0} ) \qquad Equation ( 1 )$$

The phase parameter in the sine wave term of equation (1) is replaced by the wave number k to obtain equation (2). Equation (2) represents a function capable of presenting the first distribution data.

$$I ( k ) = a ( k ) + b ( k ) cos ( 2 kh + {φ}_{0} ) \qquad Equation ( 2 )$$

After performing the phase extraction process on equation (2), the distribution relationship between the phase and the wave number as shown in FIG. 5 can be obtained. The sloped straight line in FIG. 5 can be expressed by equation (3) below, where P is the phase.

$$P = 2 kh + {φ}_{0} \qquad Equation ( 3 )$$

Equation (3) represents a function capable of presenting the second distribution data. The slope in equation (3) is “2h”, and thus one half of the slope of the sloped straight line is the hole depth h of the hole structure. The measurement unit (for example, nm) of the wavelength in equation (1) is the measurement unit of the hole depth h. Accordingly, the hole depth of the hole structure can be determined.

Regarding the phase extraction process, there are numerous methods to extract the phase information from equation (2), so as to convert the first distribution data into the second distribution data as the distribution relationship between the phase and the wave number.

In some embodiments, Hilbert transform may be used. Since equation (2) is a cosine function, a sine function with a 90-degree phase shift can be obtained after the Hilbert transform, and then an arctangent function of a real part term of the cosine function and an imaginary part term of the sine function is determined to obtain the second distribution data.

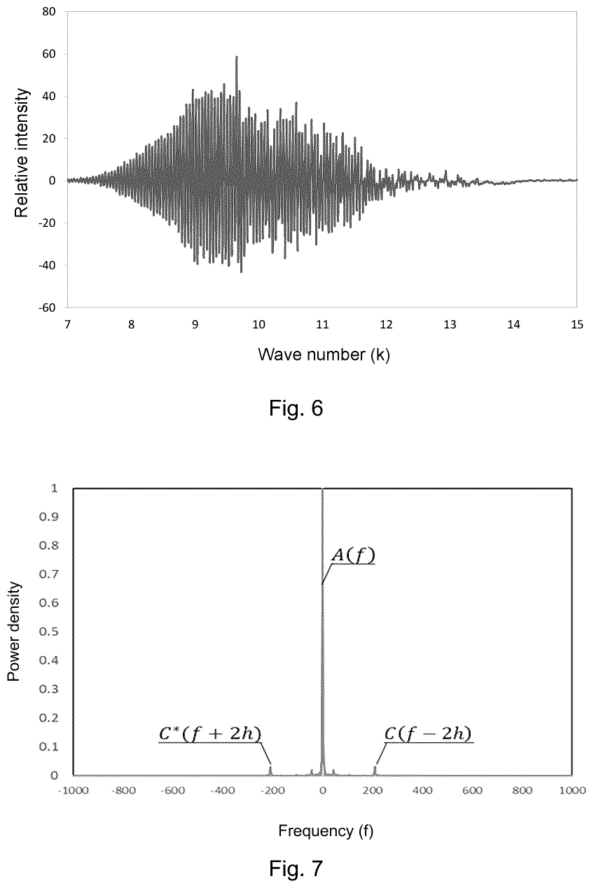

More specifically, in the phase extraction process of this embodiment, the intensity of a background reflected light that changes along with the wavelength (already converted to the wave number in equation (2)) of the incident light is removed, so that equation (2) is re-written to a function S(k) as equation (4). A relationship diagram of the intensity and the wave number of the reflected light with the DC term removed is as shown in FIG. 6. Wherein, φ is (2kh+φ₀). By performing the Hilbert transform on the function S(k), a function Ŝ(k) with a 90-degree phase shift is obtained as equation (5).

$$S ( k ) = b ( k ) cos ( φ ) \qquad Equation ( 4 )$$

$$\hat{S} ( k ) = b ( k ) sin ( φ ) \qquad Equation ( 5 )$$

Based on equation (4) and equation (5), a function of an analytical signal Sₐ(k) is as shown in equation (6). The analytical signal Sₐ(k) represents a distribution function between the wave number and a signal value. The calculation required for phase extraction performed on the analytical signal Sₐ(k) is as shown in equation (7); the real part term and the imaginary part term of the analytical signal Sₐ(k) are individually divided, and an arctangent function is determined to obtain a corresponding phase value of the corresponding wave number k. Thus, further based on a relational expression that φ is (2kh+φ₀), the distribution relationship (similar to FIG. 5) between each wave number k and the corresponding phase value, as the second distribution data, can be obtained. The distribution relationship is a sloped straight line, and one half of the slope (that is, 2h) of the sloped straight line is the hole depth h of the hole structure.

$${S}_{a} ( k ) = S ( k ) + j \hat{S} ( k ) \qquad Equation ( 6 )$$

$$φ ( k ) = {tan}^{- 1} ( \frac{Imag ( {S}_{a} ( k ) )}{Real ( {S}_{a} ( k ) )} ) = 2 kh + {φ}_{0} \qquad Equation ( 7 )$$

In some other embodiments, the phase extraction process can also obtain the distribution relationship between the phase and the wave number by means of a Fourier transform. More specifically, in the phase extraction process of this embodiment, Euler's formula conversion is first performed on equation (2) to obtain the function of equation (8).

$$\begin{matrix}I ( k ) = a ( k ) + b ( k ) cos ( 2 kh + {φ}_{0} ) \\ = a ( k ) + \frac{b ( k )}{2} {e}^{j {φ}_{0}} {e}^{j 2 kh} + \frac{b ( k )}{2} {e}^{- j {φ}_{0}} {e}^{- j 2 kh} \\ = a ( k ) + c ( k ) {e}^{j 2 kh} + c * ( k ) {e}^{- j 2 kh}\end{matrix} \qquad Equation ( 8 )$$

Wherein,

$$c ( k ) = \frac{b ( k )}{2} {e}^{j {φ}_{0}} .$$

Moreover, a Fourier transform is performed on equation (8) as intermediate data to obtain the spectrogram shown in FIG. 7, which presents the distribution relationship between a power density and a frequency f. Equation (9) is presented after performing the Fourier transform on equation (8), where c(f-2h) is a non-conjugate term, c*(f+2h) is a conjugate term, A(f) is the power density value of the DC term (with the frequency being 0).

$$FT ( I ( k ) ) = A ( f ) + C ( f - 2 h ) + C * ( f + 2 h ) \qquad Equation ( 9 )$$

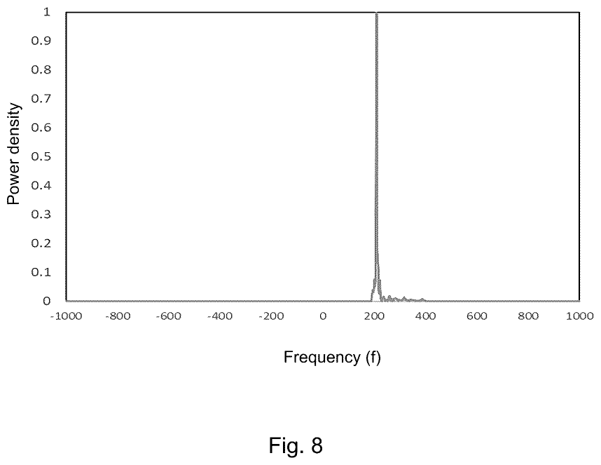

Moreover, one of the non-conjugate term and the conjugate term is preserved while the rest are removed, as the spectrogram after processing as shown in FIG. 8. That is, the waveform (referring to FIG. 7 and FIG. 8) represented by the non-conjugate term or the conjugate term is preserved, and the removed parts are filled by a plurality of data points having a power density in a fixed value (for example, 0), so as to maintain the overall data length to correctly calculate phase information later. Assuming that the conjugate term is removed, equation (10) is obtained after performing inverse Fourier transform on equation (9).

$$IFT = c ( k ) {e}^{j 2 kh} = \frac{b ( k )}{2} {e}^{j ( {φ}_{0} + 2 kh )} \qquad Equation ( 10 )$$

Equation (10) may be used to obtain the corresponding phase of each wave number k to form the distribution relationship, as the second distribution data. A straight line (a relational expression between the phase and the wave number, with a function being φ(k)=φ₀+2kh) similar to that shown in FIG. 5 can be obtained after performing phase processing on equation (10). This straight line is a sloped straight line, and one half of the slope (that is, 2h) of this sloped straight line is the hole depth h of the hole structure. In the use of operational expressions (using an instruction imag), an example shown in equation (11) can be used:

$$φ ( k ) = imag ( \frac{b ( k )}{2} {e}^{j ( {φ}_{0} + 2 kh )} ) \qquad Equation ( 11 )$$

In some other embodiments, the phase extraction process may also directly obtain the corresponding function based on the first distribution data by means of curve fitting, further obtaining the second distribution data representing the distribution relationship between the phase and the wave number based on the obtained function and the corresponding parameters. There are numerous algorithms capable of achieving calculations of curve fitting, and, for example but not limited to, the Levenberg-Marquardt (LM) method is one of them.

More specifically, by means of curve fitting of the first distribution data, a function (a function capable of depicting the first distribution data, that is, equation (2)) may be directly obtained. In addition to directly obtaining the hole depth h of the hole structure from the function, the distribution relationship between the required wave number in the phase extraction process and the corresponding phase can also be further obtained for further comparison and inspection.

In an embodiment of the present invention, by obtaining the hole depth of the hole structure using the relationship between the phase and the wave number, since correlation information between the phase and the wave number is used, the method of obtaining the hole depth based on the correlation information between the phase and the wave number provides a higher resolution compared with a method of obtaining the hole depth by using the frequency as a main parameter.

When a spectral interferometer is used, the detection light provided to a detection target has characteristics that the wavelength thereof changes within an interval, and a synthetic wavelength formed can be represented by equation (20), where λₘₐₓ is the longest wavelength within the interval, and λₘᵢₙ is the shortest wavelength within the interval.

$${λ}_{s} = \frac{{λ}_{max} {λ}_{min}}{{λ}_{max} - {λ}_{min}} \qquad Equation ( 20 )$$

In a method of estimating dimension information (for example, height or depth) based on characteristics of changes resulted from a light path difference, a minimum change that can be observed is δh (that is, the resolution). Moreover, in a method of determining a degree of phase shift by a peak value of a spectrogram after the Fourier transform to estimate dimension information, the peak value in the spectrogram can represent a period number of the light interference fringes. The degree of phase shift is associated with the period number of a sine wave interference pattern. The length of each period is 2π, and thus a product of the period number and 2π is the total phase shift. In this method, the equation of the resolution δh is as equation (21), wherein the total phase shift δφ in the calculation is about 2π.

$$δ h = \frac{{δφλ}_{s}}{4 π} = \frac{{λ}_{s}}{2} \qquad Equation ( 21 )$$

On the other hand, as a comparison, there is a method similarly based on the Fourier transform but using the phase and the wave number information and being associated with the conjugate term (that is, only preserving one of the real part term and the imaginary part term). In this method using the phase information, the degree of phase shift changes along with the light path difference, and the total phase shift δφ is as shown in equation (22), where N is the fringe period number (the integer part) in the interference fringes, ε is the remaining part (the decimal part) of the pattern of the interference fringes, and F is the number of frames.

$$δφ = \frac{2 π ( N + ε )}{F} \qquad Equation ( 22 )$$

Moreover, the calculation of the resolution δh is as shown in equation (23).

$$δ h = ( \frac{N + ε}{F} ) \frac{{λ}_{s}}{2} \qquad Equation ( 23 )$$

Accordingly, take a wavelength ranging between 450 nm and 900 nm, the number of frames as 900, and the actual depth size as 202.3 μm for example.

For a method of obtaining the hole depth by using the frequency as the main parameter, the calculation for the resolution thereof is as shown in equation (24):

$$δ h = \frac{{λ}_{s}}{2} = \frac{\frac{0.45 * 0.9}{0.9 - 0.45}}{2} = 0.45 ( μm ) \qquad Equation ( 24 )$$

For a method of using the phase and the wave number information and being associated with the conjugate term, the calculation for the resolution thereof is as shown in equation (25):

$$δ h = ( \frac{N + ε}{F} ) \frac{{λ}_{s}}{2} = ( \frac{364.14}{900} ) \frac{0.9}{2} = 0.1 \; 82 ( μm ) \qquad Equation ( 25 )$$

It is seen from the calculation results based on equation (24) and equation (25) that, for the method of obtaining hole depth information by using the correlation between the phase and the wave number in the embodiments of the present invention, compared with a method of determining the degree of phase shift merely based on the peak value of a spectrogram after the Fourier transform, the resolution obtained by the embodiments of the present invention is increased by nearly 2.5 times; that is, it is apparent that the accuracy of the size of the hole depth can be effectively enhanced.

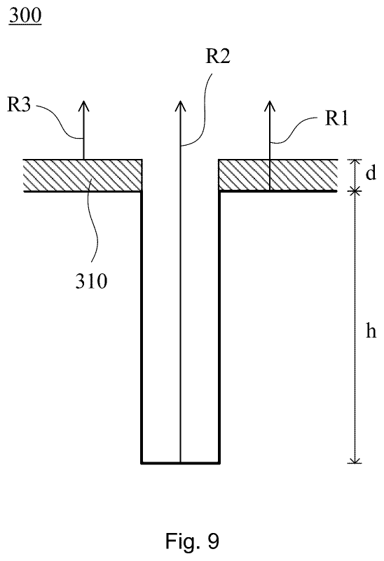

Refer to FIG. 9 showing a schematic diagram of a hole structure having an oxide layer. When a surrounding surface of the hole structure 300 has a light permeable film-like oxide layer 310, in addition to forming the first reflected light R1 on the surrounding surface of the hole structure 300 and forming the second reflected light R2 at the hole bottom of the hole structure 300, the incident light also forms a third reflected light R3 on a top surface of the oxide layer 310.

Information of the reflected lights can be captured by the light interference measurement device 100 shown in FIG. 2, and the occurrence of interference among these reflected lights and the corresponding period presented can be similarly used as the basis for determining the hole depth h and an oxide layer thickness d.

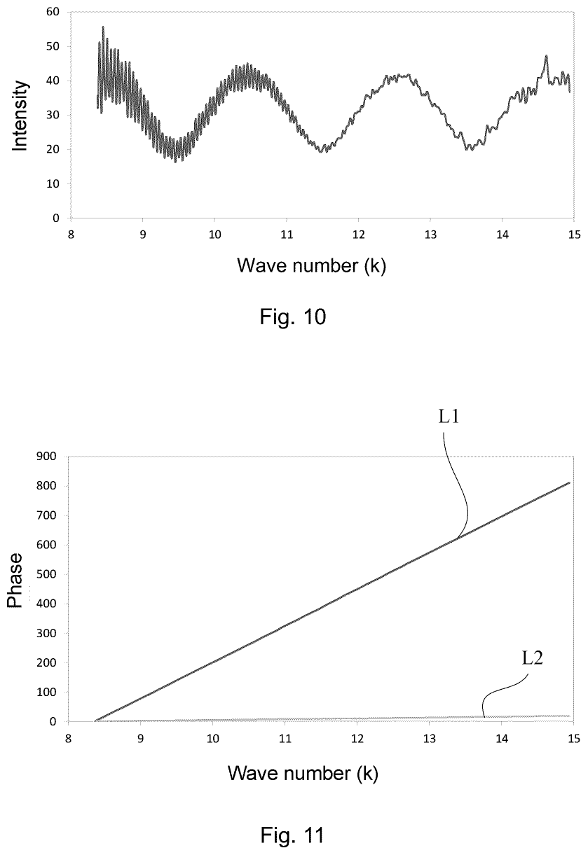

Refer to FIG. 10 showing a relationship diagram of the intensity and a wave number of a reflected light of a hole structure having an oxide layer. The waveform in a low frequency and having a large amplitude in the drawing is a light intensity distribution of an interference light formed by the first reflected light R1 and the third reflected light R3, and this distribution relationship directly corresponds to information of the oxide layer thickness d. On the other hand, the waveform in a high frequency and having a small amplitude in the drawing is a light intensity distribution of an interference light formed by the second reflected light R2 and the third reflected light R3, and this distribution relationship does not directly correspond to the hole depth h. The waveform in a high frequency and having a small amplitude presents a form of a waveform with a waveform of a low frequency and a large amplitude as a carrier wave.

In the embodiment in which the surrounding surface of the hole structure 300 has the light permeable oxide layer 310, the relationship between the phase and the wave number of the interference light formed by the first reflected light R1 and the third reflected light R3 can be expressed as equation (26) below based on the Fresnel equations. Wherein, φ₂ is the phase of the interference light formed by the first reflected light R1 and the third reflected light R3. N₁(k) is the index of refraction (that is, the index of refraction passing through is also different based on different wavelengths of incident lights) of the oxide layer that changes along with the wave number. φₙₒₙₗᵢₙₑₐᵣ is a non-linear term of such film-like oxide layer.

$${φ}_{2} = 2 {kN}_{1} ( k ) d + {φ}_{nonlinear} \qquad Equation ( 26 )$$

Moreover, the relationship between the phase and the wave number of the interference light formed by the second reflected light R2 and the third reflected light R3 can be expressed as equation (27) below. Wherein, φ₁ is the phase of the interference light formed by the second reflected light R2 and the third reflected light R3. φ₀ is the DC term.

$${φ}_{1} = ( 2 kh - ( 2 {kN}_{1} ( k ) d + {φ}_{nonlinear} ) + {φ}_{0} ) \qquad Equation ( 27 )$$

From the relationship (the first distribution data) between the intensity and the wave number of the reflected light shown in FIG. 10, the second distribution data between the phase and the wave number can be obtained by a phase extraction process (a means of curve fitting is used in this embodiment). Wherein, a function fitted by φ₁ is as shown by equation (28), and a function fitted by φ₂ is as shown by equation (29).

$${φ}_{linear {fit}_{1}} ( k ) = 2 k ( h - {N}_{1} ( k ) d ) + {φ}_{0} \qquad Equation ( 28 )$$

$${φ}_{linear {fit}_{2}} ( k ) = 2 {kN}_{1} ( k ) d \qquad Equation ( 29 )$$

Refer to FIG. 11 showing a relationship diagram of the phase and the wave number of the embodiment in FIG. 10. Between the two straight lines in FIG. 11, the straight line L1 represents equation (28), and the straight line L2 represents equation (29) to depict the relationship between the phase and the wave number. The oxide layer thickness d of the film-like oxide layer 310 may be directly obtained based on the slope value of the straight line L2, and it is known from equation (29) that, ½ of the slope value of the straight line L2 is the thickness information of the oxide layer 310.

On the other hand, it is known from equation (27) and equation (28) that, the slope value obtained from equation (28) includes related information of the hole depth h and the oxide layer thickness d, and the hole depth h is much greater than the oxide layer thickness d. Thus, the slope value obtained from equation (28) is greater than the slope value obtained from equation (29). That is to say, the second distribution data in FIG. 11 presents two straight lines, the slope value of the straight line having a greater slope between these two straight lines includes information of the hole depth h and the oxide layer thickness d, and the slope value of the straight line having a smaller slope between these two straight lines is information of the oxide layer thickness d.

Further, it is known from equation (27) and equation (28) that, the slope value obtained from equation (28) is not purely information of the h but is information from which N₁(k)d is removed. Accordingly, to obtain the correct information of the hole depth h, the removed information needs to be added, that is, as the algorithm shown by equation (30).

$$h = \frac{d}{dk} ( {φ}_{linear {fit}_{1}} ( k ) + {φ}_{linear {fit}_{2}} ( k ) ) / 2 \qquad Equation ( 30 )$$

Thus, by adding the slope value obtained from equation (29) to the slope obtained from equation (28) and then dividing by 2, the hole depth h can be obtained. Accordingly, when the surrounding surface of the hole structure 300 has the light permeable oxide layer 310, phase data in the first distribution data may present phase information contributed by phase information of the hole depth and phase information contributed by the film, and the second distribution data may present two straight lines. Wherein, the slope value of the one having a greater slope between the two straight lines is a first value, and a slope value of the one having a smaller slope between the two straight lines is a second value. One half of the second value is the oxide layer thickness d of the oxide layer 310, and one half of a sum of the first value and the second value is the hole depth h of the hole structure 300. The wavelength unit of the reflectance spectrum is the measurement unit of the hole depth h and the oxide layer thickness d.

Accordingly, by obtaining the second distribution data presented between the phase and the wave number, the hole depth h and the oxide layer thickness d can be determined. Therefore, other mathematical processes of distribution relationships (the second distribution data) between the phase and the wave number obtained from relationship (the first distribution data) between the intensity and the wave number of a reflected light are all applicable. For example, since the relationship (the first distribution data) between the intensity and the wave number of the reflected light presents a corresponding relationship associated with a hole depth or a film thickness in different periods, part of signals can be first filtered out to obtain corresponding straight lines (the distribution relationship between the phase and the wave number) one after another, and two straight lines are placed together to similarly present the distribution relationship diagram as shown in FIG. 11, so as to calculate the hole depth h and the oxide layer thickness d as described above.

Various functions and computations performed in the form of software described above may be accomplished by means of executing a computer program stored in a non-volatile computer-readable storage medium. The computer program is stored in the medium, and includes a plurality of instructions to prompt an electronic device (for example, the computing processing device 200, various computer apparatuses, network apparatuses or other electronic apparatuses) or a processor to perform the method for measuring a hole depth using phase extraction information from a reflectance spectrum as described in the various embodiments of the present invention.

In conclusion, based on the relationship between the intensity and the wave number of the reflected light, the relationship between the phase and the wave number is obtained by means of conversion. Then, with the distribution relationship presenting a form of a straight line, the slope value is calculated to obtain information of the hole depth h of the hole structure 300, and information of the oxide layer thickness d can also be further obtained. Thus, the measurement resolution is increased and the accuracy is also enhanced.

The present disclosure is illustrated by various aspects and embodiments. However, persons skilled in the art understand that the various aspects and embodiments are illustrative rather than restrictive of the scope of the present disclosure. After perusing this specification, persons skilled in the art may come up with other aspects and embodiments without departing from the scope of the present disclosure. All equivalent variations and replacements of the aspects and the embodiments must fall within the scope of the present disclosure. Therefore, the scope of the protection of rights of the present disclosure shall be defined by the appended claims.

What is claimed is:

1. A method for measuring a hole depth using phase extraction information from a reflectance spectrum, comprising:
acquiring a reflectance spectrum from a target region, the target region comprising therein a hole structure with a high aspect ratio;
obtaining first distribution data between the intensity and a wave number of a reflected light based on the reflectance spectrum;
converting the first distribution data by a phase extraction process into second distribution data between a phase and the wave number; and
determining a hole depth of the hole structure according to a slope value of at least one straight line presented by the second distribution data, and using a wavelength unit of the reflectance spectrum as a measurement unit of the hole depth.

2. The method according to claim 1, wherein when a surrounding surface of the hole structure has a light permeable oxide layer, phase data in the first distribution data defines a hole depth phase and a film phase, and the second distribution data presents two straight lines, wherein a slope value of a straight line having a greater slope between the two straight lines is a first value, and a slope value of a straight line having a smaller slope between the two straight lines is a second value, one half of the second value is a thickness of the oxide layer, one half of a sum of the first value and the second value is a hole depth of the hole structure, and a wavelength unit of the reflectance spectrum is a measurement unit of the thickness of the oxide layer.

3. The method according to claim 1, wherein when the second distribution data presents one single straight line, one half of the slope value of the straight line is the hole depth of the hole structure.

4. The method according to claim 3, wherein when a surrounding surface of the hole structure has a light permeable oxide layer, phase data in the first distribution data defines a hole depth phase and a film phase, and the second distribution data presents two straight lines, wherein a slope value of a straight line having a greater slope between the two straight lines is a first value, and a slope value of a straight line having a smaller slope between the two straight lines is a second value, one half of the second value is a thickness of the oxide layer, one half of a sum of the first value and the second value is a hole depth of the hole structure, and a wavelength unit of the reflectance spectrum is a measurement unit of the thickness of the oxide layer.

5. The method according to claim 1, wherein the phase extraction process comprises:
removing a DC term from the first distribution data;
performing a Hilbert transform to obtain an analytical signal having a real part term in a cosine form and an imaginary part term in a sine form; and
obtaining a distribution relationship between the phase and the wave number as the second distribution data based on an arctangent function of the real part term and the imaginary part term.

6. The method according to claim 5, wherein when a surrounding surface of the hole structure has a light permeable oxide layer, phase data in the first distribution data defines a hole depth phase and a film phase, and the second distribution data presents two straight lines, wherein a slope value of a straight line having a greater slope between the two straight lines is a first value, and a slope value of a straight line having a smaller slope between the two straight lines is a second value, one half of the second value is a thickness of the oxide layer, one half of a sum of the first value and the second value is a hole depth of the hole structure, and a wavelength unit of the reflectance spectrum is a measurement unit of the thickness of the oxide layer.

7. The method according to claim 1, wherein the phase extraction process comprises:
converting the first distribution data into intermediate data having a real part term and an imaginary part term;
performing a Fourier transform;
performing a step of removing and filling points to preserve only one of the real part term and the imaginary part term, and to remove other data and fill a plurality of data points having a power density in a fixed value so as to maintain a data length;
performing an inverse Fourier transform; and
obtaining the distribution relationship between the phase and the wave number, as the second distribution data.

8. The method according to claim 7, wherein when a surrounding surface of the hole structure has a light permeable oxide layer, phase data in the first distribution data defines a hole depth phase and a film phase, and the second distribution data presents two straight lines, wherein a slope value of a straight line having a greater slope between the two straight lines is a first value, and a slope value of a straight line having a smaller slope between the two straight lines is a second value, one half of the second value is a thickness of the oxide layer, one half of a sum of the first value and the second value is a hole depth of the hole structure, and a wavelength unit of the reflectance spectrum is a measurement unit of the thickness of the oxide layer.

9. A non-volatile computer-readable storage medium, having a computer program stored therein, the computer program operable to be loaded into a computing processing device, and to prompt the computing processing device to perform the method according to claim 1.

10. A measurement system for measuring a hole depth using phase extraction information from a reflectance spectrum, comprising:
a light interference measurement device, operable to acquire a reflectance spectrum from a target region; and
a computing processing device, coupled to the light interference measurement device, the computing processing device operable to perform the method according to claim 1.

11. The measurement system according to claim 7, wherein the light interference measurement device is controlled to perform one scanning and measurement operation on only one single hole structure within the target region at a time.
